(19) United States
(12) Patent Application Publication
(10) Pub. No.: US 2014/0195175 A1
(43) Pub. Date: Jul. 10, 2014

(54) MEASURING DIELECTRIC BREAKDOWN IN A DYNAMIC MODE

(71) Applicant: INTERNATIONAL BUSINESS MACHINES CORPORATION, Armonk, NY (US)

(72) Inventors: Eduard A. Cartier, New York, NY (US); Charles LaRow, Burlington, VT (US); Travis S. Merrill, Rutland, VT (US); Ernest Y. Wu, Essex Junction, VT (US)

(73) Assignee: INTERNATIONAL BUSINESS MACHINES CORPORATION, Armonk, NY (US)

(21) Appl. No.: 13/734,075

(22) Filed: Jan. 4, 2013

(51) Int. Cl. G01R 31/14; G06F 17/10

(52) U.S. Cl. CPC G01R 31/14; G06F 17/10
USPC 702/58

(57) ABSTRACT

Embodiments of the present invention provide a method, system, and program product for testing a semiconductor device to measure dielectric breakdown. A computer applies a plurality of stress voltages to a semiconductor device under test. The computer determines a plurality of current measurements until a failure criteria occurs, using a predefined voltage ramp rate and a predefined plurality of stress voltage steps, wherein the number of the plurality of current measurements is less than or equal to the number of the predefined plurality of voltage steps. The computer identifies a stress voltage at which the semiconductor device fails. The computer calculates a frequency dependent voltage acceleration factor based on the quotient of the natural log of the voltage at which the semiconductor device under test failed to the natural log of the predetermined voltage ramp rate.

### FIELD OF THE INVENTION

The present invention relates generally to the field of testing semiconductor devices, and more particularly to testing for dielectric breakdown in a semiconductor device and calculating a voltage dependent acceleration factor.

### BACKGROUND OF THE INVENTION

Semiconductors are the foundation of modern electronics, including radio, computers, and telephones. Semiconductor-based electronic components include digital and analog integrated circuits, transistors, solar cells, and various types of diodes, such as, silicon controlled rectifier, photodiodes, and light-emitting diodes (LED). Conventional semiconductor devices suffer from various reliability and performance stresses, such as dielectric breakdown, that can affect performance.

The operating parameters of a semiconductor device may be adjusted to increase performance and reliability. However, there is typically a tradeoff between the performance and lifetime of the semiconductor device. Adjusting the operating parameters to achieve increased performance typically results in an increase in stresses, such as dielectric-breakdown. The tradeoff between performance and lifetime may be more accurately balanced if dielectric breakdown in the semiconductor device can be measured. Currently, near the end of fabrication of a semiconductor device, a dielectric test is conducted to determine both the quality and reliability of the dielectric material contained therein. Traditional dielectric reliability evaluations focus on time-dependent dielectric breakdown and involve time-domain stress with explicit time measurements. However, such an approach is time-consuming, involves instrumental usage overhead, and can not be implemented in inline testing or in a manufacturing environment.

### SUMMARY

Embodiments of the present invention provide a method, system, and program product for testing a semiconductor device to measure dielectric breakdown. A computer applies a plurality of stress voltages to a semiconductor device under test. The computer determines a plurality of current measurements until a failure criteria occurs, using a predefined voltage ramp rate and a predefined plurality of stress voltage steps, wherein the number of the plurality of current measurements is less than or equal to the number of the predefined plurality of voltage steps. The computer identifies a stress voltage at which the semiconductor device fails. The computer calculates a frequency dependent voltage acceleration factor based on the quotient of the natural log of the voltage at which the semiconductor device under test failed to the natural log of the predetermined voltage ramp rate.

In certain embodiments, the predefined voltage ramp rate is defined as R(rate)=dVi/dt, wherein Vi is a stress voltage in the plurality of stress voltages, and wherein t is the duration of the stress voltage. In other embodiments, determining the plurality of current measurements includes determining a current and identifying a voltage at each step included in the predefined plurality of voltage steps. In additional embodiments, the plurality of stress voltages produces alternating current, direct current, or both. In yet still other embodiments, the frequency dependent voltage acceleration factor is defined by the following formula: n={Ln(V_{FAIL})/LnR}−1, wherein V_{FAIL} is the stress voltage at which the semiconductor device fails, and wherein R is the predefined voltage ramp rate.

In alternative embodiments, the failure criteria includes at least one of the following: the applied stress voltage being greater than or equal to a predetermined maximum voltage; a measured current of the plurality of current measurements being greater than or equal to a predetermined maximum current; or a logarithmic slope of a current versus a voltage curve, derived from the plurality of current measurements and the plurality of stress voltages, increases by a factor two to fives times greater than or equal to a previously calculated logarithmic slope included in the current versus the voltage curve or a predetermined slope.

### BRIEF DESCRIPTION OF THE SEVERAL VIEWS OF THE DRAWINGS

FIG. 1 is a functional block diagram illustrating a voltage dependent dielectric breakdown testing environment, in accordance with an embodiment of the present invention.

FIG. 2A illustrates an exemplary voltage ramp wave-form utilized by a voltage dependent acceleration factor program during dielectric testing of a device under test within the voltage dependent dielectric breakdown testing environment of FIG. 1, in accordance with an embodiment of the present invention.

FIG. 2B illustrates an exemplary current-voltage graph illustrating a plurality of current measurements in voltage dependent dielectric breakdown testing environment of FIG. 1, in accordance with an embodiment of the invention.

FIG. 3 is a flowchart depicting the operational steps of a voltage dependent acceleration factor program, in accordance with an embodiment of the invention.

FIG. 4 depicts a block diagram of components of the computing device of FIG. 1, in accordance with an embodiment of the present invention.

### DETAILED DESCRIPTION

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer-readable medium(s) having computer readable program code/instructions embodied thereon.

For purposes herein, an “insulator” is a relative term that means a material or structure that allows substantially less (<95%) electrical current to flow than does a “conductor.” The dielectrics (insulators) mentioned herein can, for example, be grown from either a dry oxygen ambient or steam and then patterned. Alternatively, the dielectrics herein may be formed from any of the many candidate high dielectric constant (high-k) materials, including but not limited to silicon nitride, silicon oxynitride, a gate dielectric stack of SiO₂ and Si₃N₄, and metal oxides like tantalum oxide. The thickness of dielectrics herein may vary contingent upon the required device performance.

Any combination of computer-readable media may be utilized. Computer-readable media may be a computer-readable signal medium or a computer-readable storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of a computer-readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

A computer-readable signal medium may include a propagated data signal with computer-readable program code embodied therein, for example, in baseband or as part of a carrier wave. Such a propagated signal may take any of a variety of forms, including, but not limited to, electro-magnetic, optical, or any suitable combination thereof. A computer-readable signal medium may be any computer-readable medium that is not a computer-readable storage medium and that can communicate, propagate, or transport a program for use by or in connection with an instruction execution system, apparatus, or device.

Program code embodied on a computer-readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on a user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer, other programmable data processing apparatus, or other devices to function in a particular manner, such that the instructions stored in the computer-readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer-implemented process such that the instructions which execute on the computer or other programmable apparatus provide processes for implementing the functions/acts specified in the flowchart and/or block diagram block or blocks.

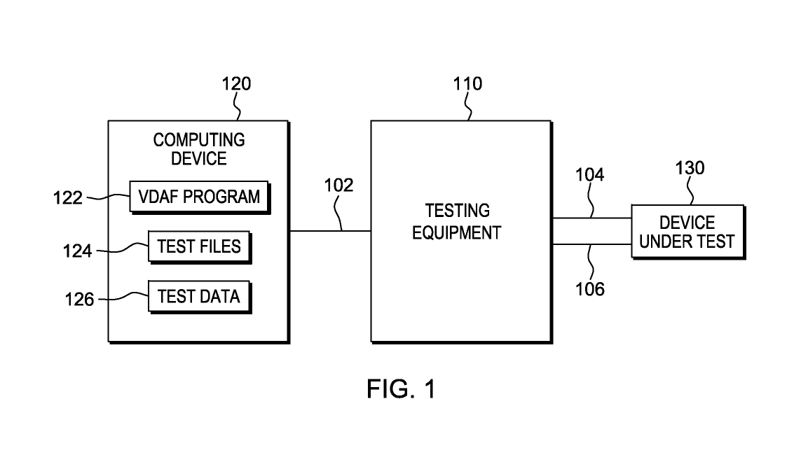

The present invention will now be described in detail with reference to the Figures. FIG. 1 is a functional block diagram illustrating a voltage dependent dielectric breakdown (VDDB) testing environment, generally designated 100, in accordance with an embodiment of the present invention. VDDB testing environment 100 includes device under test (DUT) 130, testing equipment 110, and computing device 120. In another embodiment testing equipment 110, computing device 120, DUT 130, or any combination thereof may be depicted as a single entity. Although not shown, VDDB testing environment 100 may include additional connections than those shown in FIG. 1.

In accordance with an embodiment of the invention, DUT 130 can be associated with testing equipment 110 via test input line 104 and test output line 106, in accordance with an embodiment of the invention. Device under test 130 can be a semiconductor device, for example, a die on a wafer or the resulting packaged part, transistor, solar cell, digital or analog integrated circuit, or a type of diode, for example, a light emitting diode (LED), silicon rectifier, or photodiode. For example, DUT 130 may be a semiconductor device coming off an assembly line that is to be given a final in-line test. In general, DUT 130 may be any device manufactured utilizing a semiconducting material, for example, silicon dioxide.

Testing equipment 110 may be associated with computing device 120, via communications link 102, and DUT 130, via test input line 104 and test output line 106, in accordance with an embodiment of the invention. Typically, testing equipment 110 is any testing equipment that can apply voltage to a semiconductor device, for example, DUT 130, by test input line 104, measure current and voltage readings of the semiconductor device by test output line 106, and transmit current and voltage measurements or readings to a computing device, for example, computing device 110, via communications line 102. Further, testing equipment 110 may control voltage pulse repetition rate (frequency), width, delay, and high- and low-levels. Further still, testing equipment 110 may generate various types of voltage wave-forms, for example, static, dynamic, unipolar, bipolar, symmetric, asymmetric, or any combination thereof. In another embodiment, testing equipment 110 may store the current and voltage measurement data locally or externally via a networked computing device or storage device. In general, testing equipment 110 may be any testing equipment capable of applying a voltage pulse to a semiconductor device, for example, DUT 130, measuring current and voltage, and produce current and voltage measurement data.

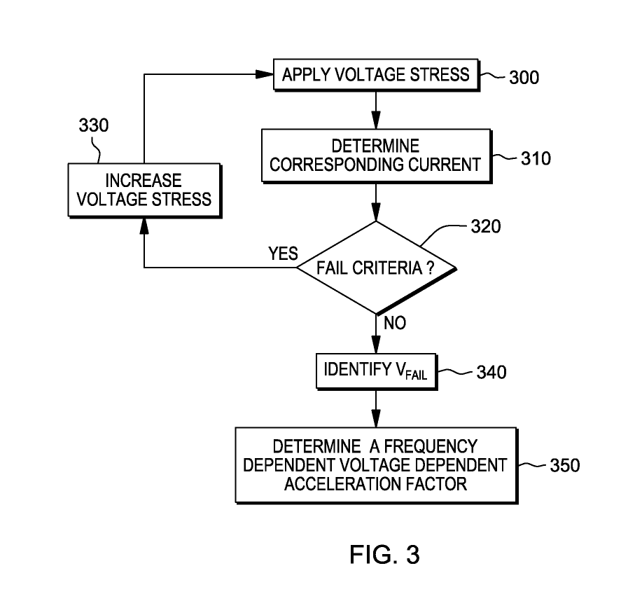

Computing device 120 is associated with testing equipment 110, via communications link 102, in accordance with an embodiment of the invention. Computing device 120 includes voltage dependent acceleration factor (VDAF) program 122, test files 124, test data 126. In an embodiment, VDAF program 122, test files 124 and/or test data 126 may be stored on an external storage device, for example, external storage devices 418. Computing device 120 can transmit data to and receive data from testing equipment 110 via communications link 102. Further, computing device 120 can transmit instructions to testing equipment 110. In general, computing device 120 may be any computing device capable of calculating a voltage dependent acceleration factor, executing VDAF program 122, and communicating with testing equipment 110. In accordance with an embodiment of the invention, VDAF program 122, which will be discussed in more detail below with reference to FIG. 3, may test for dielectric breakdown in a semiconductor device, for example, DUT 130.

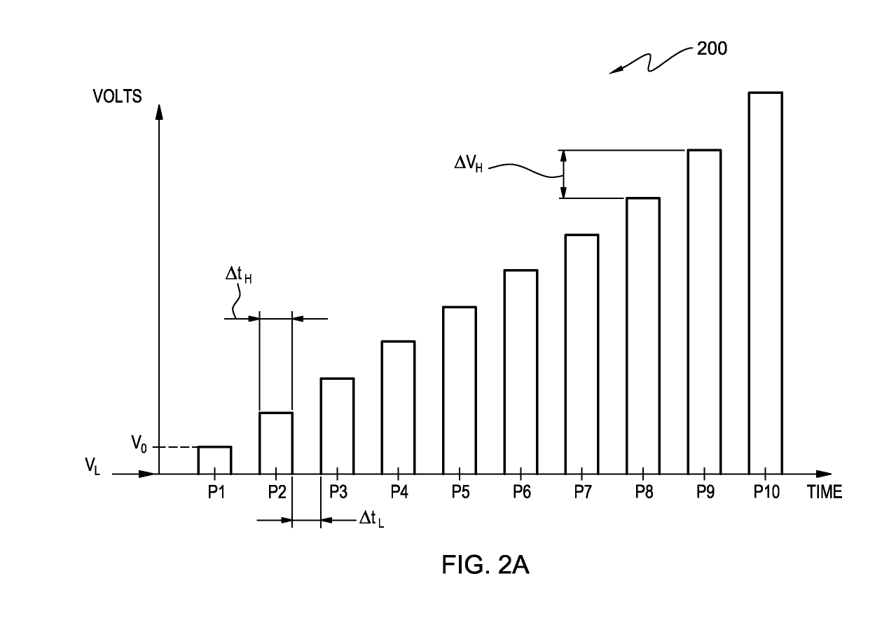

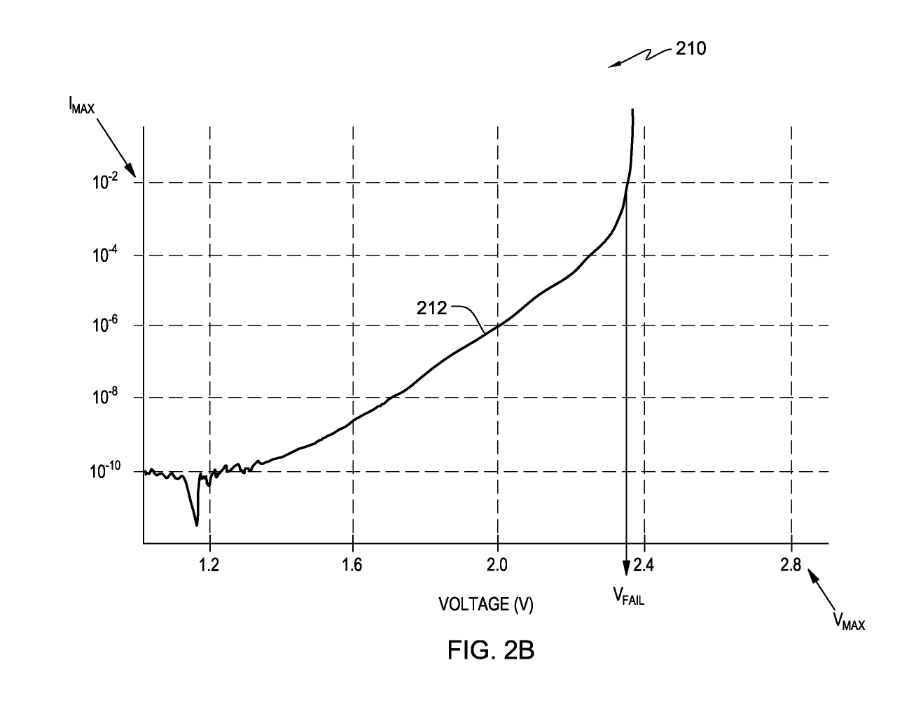

Test files 124 can include predefined testing parameters, for example, voltage ramp rate (R), maximum current (I_{MAX}), maximum voltage (V_{MAX}), and start voltage (V₀), utilized by VDAF program 122 for dielectric testing. Test data 126 can include current and voltage measurement and/or reading files, for example, V_{FAIL} and I_{MEAS}, transmitted by testing equipment 110, via communications link 102, to computing device 120 during testing of DUT 130, in accordance with an embodiment of the invention. Having discussed an overview of an exemplary operating environment in which embodiments of the present invention may be implemented, we now turn to FIGS. 2A and 2B, which illustrate exemplary testing of a semiconductor device, in accordance with the invention.

FIG. 2A illustrates wave-form 200, an exemplary voltage ramp wave-form utilized by VDAF program 122 during dielectric testing of DUT 130 with the VDDB testing environment of FIG. 1, in accordance with an embodiment of the present invention. In particular, waveform 200 depicts a unipolar dynamic mode voltage ramp wave-form that includes voltage pulses P1-P10 that are depicted as bars that vary over time in strength but are uniform in duration, and are measured in volts per unit time. Dynamic mode wave-forms are wave-forms that can generate an alternating current. In one embodiment, one or more of P1-P10 may have a negative voltage polarity.

Although not show, wave-form 200 may include additional pulses beyond pulse P1-P10. In an embodiment, high pulse duration (Δt_{H}) may equal low pulse duration (Δt_{L}). However, in other embodiments Δt_{H} and Δt_{L} may not be equal, for example, Δt_{H}<Δt_{L} or Δt_{H}>Δt_{L}. Further, Δt_{H} and Δt_{L} may be any measure of time, for example, 100 ms. Start voltage (V₀) is the initial voltage that VDAF program 122, via communications link 102, instructs testing equipment 110 to apply to DUT 130, via test input line 104. In one embodiment, Δt_{L} can be uniform for each pulse, but in various embodiments Δt_{L} may be different. Voltage pulse ramp size (ΔV_{H}) is the amount that the applied voltage increases between adjacent pulses. In an embodiment, ΔV_{H} is uniform for all voltage pulses, but in various embodiments ΔV_{H} may not be uniform for all voltage pulses. As shown in FIG. 2A, wave-form 200 starts at V₀ and increases uniformly by ΔV_{H} from pulse P1 to P10.

FIG. 2B illustrates graph 210, an exemplary current-voltage graph illustrating a plurality of current measurements in VDDB testing environment 100, in accordance with an embodiment of the invention. In particular, graph 210 depicts line 212 that varies over a range of voltages. The voltage on the horizontal axis of graph 210 is the same as the voltage on the vertical axis of wave-form 200. Further, the vertical axis of graph 210 is graphed according to the current output of test output line 106. Further still, the horizontal axis of graph 210 is graphed according to the voltage input of test input line 104. VDAF program 122 initiates dielectric testing of device under test (DUT) 130 by retrieving predefined dielectric testing parameters, for example, V₀, I_{MAX}, V_{MAX}, and voltage ramp rate (R), from test files 124.

Subsequent to the retrieval, VDAF program 122, via communications link 102, instructs testing equipment 110 to apply, via test input line 104, voltage to DUT 130 in a manner compatible with wave-form 200. During application of each voltage pulse to DUT 130, VDAF program 122, via communications link 102, instructs testing equipment 110 to measure, via test output line 106, current generated by DUT 130. Subsequent to current measurement, VDAF program 122, via communications link 102, instructs testing equipment 110 to transmit, via communications link 102, the current measurement to computing device 120, wherein it is received by VDAF program 122 and stored in test data 124.

VDAF program 122 continues the application/measurement cycle until the measured current equals I_{MAX}, at which time the dielectric test fails. Subsequent to the failure, VDAF program 122, via communications link 102, instructs testing equipment 110 to record V_{FAIL} and, via communications link 102, transmit V_{FAIL} to VDAF program 122, via computing device 120, for storage in test data 124. Subsequent to the transmittal, VDAF program 122 receives the transmitted V_{FAIL} and stores the transmitted V_{FAIL} in test data 124. In addition, VDAF program 122 generates graph 210 utilizing the received current measurements stored in test data 124. In an embodiment, VDAF program 122 can generate graph 210 in real-time as data is received from testing equipment 110, in other embodiments, VDAF program 122 may generate graph 210 subsequent to dielectric test failure.

Furthermore, subsequent to receiving V_{FAIL}, VDAF program 122 calculates a voltage dependant acceleration factor for DUT 130, utilizing the following equation [1].

n={Ln(V_{FAIL})/Ln R}−1 [1]

wherein VDAF program 122 retrieves V_{FAIL} and the voltage ramp rate (R) from test data 124, and wherein R is defined by equation [2].

R=ΔVᵢ/Δγ [2]

wherein ΔVᵢ=voltage pulse=start voltage (V₀)+(n−1)*ΔV_{H}, wherein n is the voltage step number, and wherein Δγ=pulse duration. In another embodiment, R=dVᵢ/dt, wherein dVᵢ is the difference in DUT 130 applied voltage, wherein dt is the difference in time. Although not shown, voltage dependant acceleration factor, n, may be derived using any voltage acceleration model, for example, the exponential law voltage acceleration model (E model), power law voltage acceleration model, and exponential law of reciprocal voltage and field voltage acceleration model (1/V model or 1/E model).

FIG. 3 is a flowchart depicting the operational steps of VDAF program 122, in accordance with an embodiment of the invention. VDAF program 122, via communications link 102, instructs testing equipment 110 to apply voltage stress to DUT 130 as per a predefined voltage ramp rate (R) (step 300). In an embodiment, applying voltage stress to DUT 130 includes applying a plurality of stress voltages to DUT 130 as per the predefined voltage ramp rate (R). For example, voltage ramp rate can be MV/cm*s. In general, voltage ramp rate (R) may be any acceptable ramp rate capable of testing dielectric breakdown in a semiconductor device.

Concomitantly, VDAF program 122 identifies the corresponding current (I_{MEAS}) of DUT 130 (step 310). Subsequent to the measurement, VDAF program 122 determines whether a fail criterion is met (step 320). For example, the fail criteria may include a failure voltage dictated by V_{MEAS}≧V_{MAX}, a failure current dictated by I_{MEAS}≧I_{MAX}, a failure charge (Q_{MEAS}≧Q_{MAX}) or may be based on slope, wherein failure is reached when the logarithmic slope of graph 210 increases by a predefined factor compared to the previously calculated slope (typically 2.5˜5 times). If VDAF program 122 determines that the fail criterion has not been met (“no” branch decisional 320), VDAF program 122 increases voltage stress to be applied to DUT 130 according to the predefined voltage ramp rate (step 330). Subsequent to increasing the voltage stress, VDAF program 122 applies the increased voltage stress to DUT 130 (step 300). VDAF program 122 executes the stress/measure cycle (steps 300 to 330) and generates a plurality of current measurements for a predefined plurality of voltage steps or until VDAF program determines that a fail criterion is met. As such, the number of the plurality of current measurements is less than or equal to the number of the plurality of voltage steps.

If VDAF program 122 determines that a fail criterion has been met (“yes” branch decisional 320), VDAF program 122 determines the corresponding voltage at which the dielectric test failed at (V_{FAIL}) (step 340). Subsequent to the determination, VDAF program 122 determines a frequency dependent voltage acceleration factor for DUT 130 based on equation [1] above (step 350).

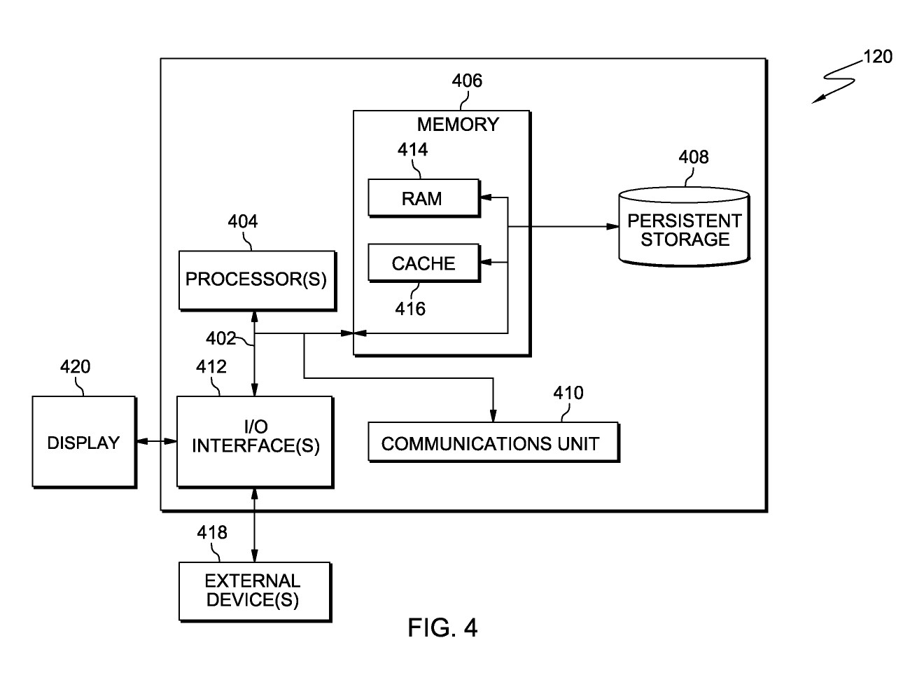

FIG. 4 depicts a block diagram of components of computing device 120 of FIG. 1, in accordance with an illustrative embodiment of the present invention. It should be appreciated that FIG. 4 provides only an illustration of one implementation and does not imply any limitations with regard to the environments in which different embodiments may be implemented. Many modifications to the depicted environment may be made.

Computing device 120 includes communications fabric 402, which provides communications between computer processor(s) 404, memory 406, persistent storage 408, communications unit 410, and input/output (I/O) interface(s) 412. Communications fabric 402 can be implemented with any architecture designed for passing data and/or control information between processors (such as microprocessors, communications and network processors, etc.), system memory, peripheral devices, and any other hardware components within a system. For example, communications fabric 402 can be implemented with one or more buses.

Memory 406 and persistent storage 408 are computer-readable storage media. In this embodiment, memory 406 includes random access memory (RAM) 414 and cache memory 416. In general, memory 406 can include any suitable volatile or non-volatile computer-readable storage media.

Voltage dependent acceleration factor (VDAF) program 122 and test data 124 are stored in persistent storage 408 for execution/or access by one or more of the respective computer processors 404 via one or more memories of memory 406. In this embodiment, persistent storage 408 includes a magnetic hard disk drive. Alternatively, or in addition to a magnetic hard disk drive, persistent storage 408 can include a solid state hard drive, a semiconductor storage device, read-only memory (ROM), erasable programmable read-only memory (EPROM), flash memory, or any other computer-readable storage media that is capable of storing program instructions or digital information.

The media used by persistent storage 408 may also be removable. For example, a removable hard drive may be used for persistent storage 408. Other examples include optical and magnetic disks, thumb drives, and smart cards that are inserted into a drive for transfer onto another computer-readable storage medium that is also part of persistent storage 408.

Communications unit 410, in these examples, provides for communications with other data processing systems or devices, including testing equipment 110. In these examples, communications unit 410 includes one or more network interface cards. Communications unit 410 may provide communications through the use of either or both physical and wireless communications links. VDAF program 122 may be downloaded to persistent storage 408 through communications unit 410.

I/O interface(s) 412 allows for input and output of data with other devices that may be connected to server computer 102. For example, I/O interface 412 may provide a connection to external devices 418 such as a keyboard, keypad, a touch screen, and/or some other suitable input device. External devices 418 can also include portable computer-readable storage media such as, for example, thumb drives, portable optical or magnetic disks, and memory cards. Software and data used to practice embodiments of the present invention, e.g., VDAF program 122 and test data 124, can be stored on such portable computer-readable storage media and can be loaded onto persistent storage 408 via I/O interface(s) 412. I/O interface(s) 412 also connect to a display 420.

Display 420 provides a mechanism to display data to a user and may be, for example, a computer monitor.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

As will be appreciated by one skilled in the art, aspects of the systems and methods herein may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

What is claimed is:

1. A method for testing a semiconductor device to measure dielectric breakdown, comprising:
a computer applying a plurality of stress voltages to a semiconductor device under test;
the computer determining a plurality of current measurements until a failure criteria occurs, using a predefined voltage ramp rate and a predefined plurality of stress voltage steps, wherein the number of the plurality of current measurements is less than or equal to the number of the predefined plurality of voltage steps;
the computer identifying a stress voltage at which the semiconductor device fails; and
the computer calculating a frequency dependent voltage acceleration factor based on the quotient of the natural log of the voltage at which the semiconductor device under test failed to the natural log of the predetermined voltage ramp rate.

2. The method of claim 1, wherein the predefined voltage ramp rate is defined as R (rate)=dVᵢ/dt, wherein V, is a stress voltage in the plurality of stress voltages, and wherein t is the duration of the stress voltage.

3. The method of claim 1, wherein the determining the plurality of current measurements includes determining a current and identifying a voltage at each step included in the predefined plurality of voltage steps.

4. The method of claim 1, wherein the plurality of stress voltages produces alternating current, direct current, or both.

5. The method of claim 4, wherein the failure criteria includes at least one of the following:
the applied stress voltage being greater than or equal to a predetermined maximum voltage;
a measured current of the plurality of current measurements being greater than or equal to a predetermined maximum current; or
a logarithmic slope of a current versus a voltage curve, derived from the plurality of current measurements and the plurality of stress voltages, increases by a factor two to fives times greater than or equal to a previously calculated logarithmic slope included in the current versus the voltage curve or a predetermined slope.

6. The method of claim 1, wherein the frequency dependent voltage acceleration factor is defined by the following formula: n={Ln(V_{FAIL})/LnR}−1, wherein V_{FAIL} is the stress voltage at which the semiconductor device fails, and wherein R is the predefined voltage ramp rate.

7. A computer system for testing a semiconductor device to measure dielectric breakdown, the computer system comprising:
one or more processors, one or more computer-readable memories, one or more computer-readable storage devices, and program instructions stored on at least one of the one or more storage devices for execution by at least one of the one or more processors via at least one of the one or more memories, the program instructions comprising:
program instructions to apply a plurality of stress voltages to a semiconductor device under test;
program instructions to determine a plurality of current measurements until a failure criteria occurs, using a predefined voltage ramp rate and a predefined plurality of stress voltage steps, wherein the number of the plurality of current measurements is less than or equal to the number of the predefined plurality of voltage steps;
program instructions to identify a stress voltage at which the semiconductor device fails; and
program instructions to calculate a frequency dependent voltage acceleration factor based on the quotient of the natural log of the voltage at which the semiconductor device under test failed to the natural log of the predetermined voltage ramp rate.

8. The computer system of claim 7, wherein the predefined voltage ramp rate is defined as R(rate)=dVᵢ/dt, wherein V, is a stress voltage in the plurality of stress voltages, and wherein t is the duration of the stress voltage.

9. The computer system of claim 7, wherein the determining the plurality of current measurements includes determining a current and identifying a voltage at each step included in the predefined plurality of voltage steps.

10. The computer system of claim 7, wherein the plurality of stress voltages produces alternating current, direct current, or both.

11. The computer system of claim 10, wherein the failure criteria includes at least one of the following:
the applied stress voltage being greater than or equal to a predetermined maximum voltage;
a measured current of the plurality of current measurements being greater than or equal to a predetermined maximum current; or
a logarithmic slope of a current versus a voltage curve, derived from the plurality of current measurements and the plurality of stress voltages, increases by a factor two to fives times greater than or equal to a previously calculated logarithmic slope included in the current versus the voltage curve or a predetermined slope.

12. The computer system of claim 7, wherein the frequency dependent voltage acceleration factor is defined by the following formula: n={Ln(V_{FAIL})/LnR}−1, wherein V_{FAIL} is the stress voltage at which the semiconductor device fails, and wherein R is the predefined voltage ramp rate.

13. A computer program product for testing a semiconductor device to measure dielectric breakdown, the computer program product comprising:
one or more computer-readable storage media and program instructions stored on the one or more computer-readable storage media, the program instructions comprising:
program instructions to apply a plurality of stress voltages to a semiconductor device under test;
program instructions to determine a plurality of current measurements until a failure criteria occurs, using a predefined voltage ramp rate and a predefined plurality of stress voltage steps, wherein the number of the plurality of current measurements is less than or equal to the number of the predefined plurality of voltage steps;
program instructions to identify a stress voltage at which the semiconductor device fails; and
program instructions to calculate a frequency dependent voltage acceleration factor based on the quotient of the natural log of the voltage at which the semiconductor device under test failed to the natural log of the predetermined voltage ramp rate.

14. The computer program product of claim 13, wherein the predefined voltage ramp rate is defined as R(rate)=dVᵢ/dt, wherein V, is a stress voltage in the plurality of stress voltages, and wherein t is the duration of the stress voltage.

15. The computer program product of claim 13, wherein the determining the plurality of current measurements includes determining a current and identifying a voltage at each step included in the predefined plurality of voltage steps.

16. The computer program product of claim 13, wherein the plurality of stress voltages produces alternating current, direct current, or both.

17. The computer program product of claim 16, wherein the failure criteria includes at least one of the following:
the applied stress voltage being greater than or equal to a predetermined maximum voltage;
a measured current of the plurality of current measurements being greater than or equal to a predetermined maximum current; or
a logarithmic slope of a current versus a voltage curve, derived from the plurality of current measurements and the plurality of stress voltages, increases by a factor two to fives times greater than or equal to a previously calculated logarithmic slope included in the current versus the voltage curve or a predetermined slope.

18. The computer program product of claim 13, wherein the frequency dependent voltage acceleration factor is defined by the following formula: n={Ln(V_{FAIL})/LnR}−1, wherein V_{FAIL} is the stress voltage at which the semiconductor device fails, and wherein R is the predefined voltage ramp rate.
